(19) United States
(12) Patent Application Publication
(10) Pub. No.: US 2014/0001031 A1
(43) Pub. Date: Jan. 2, 2014

(54) DEVICE FOR PRODUCING NANOPARTICLES AT HIGH EFFICIENCY, USE OF SAID DEVICE AND METHOD OF DEPOSITING NANOPARTICLES

(71) Applicants: Etienne Quesnel, Meylan (FR); Viviane Muffato, Le Gua (FR); Stephanie Parola, La Mure (FR)

(72) Inventors: Etienne Quesnel, Meylan (FR); Viviane Muffato, Le Gua (FR); Stephanie Parola, La Mure (FR)

(73) Assignee: Commissariat A L'Energie Atomique et aux Energies Alternatives, Paris (FR)

(21) Appl. No.: 14/002,588

(22) PCT Filed: Feb. 27, 2012
(86) PCT No.: PCT/FR2012/000069

§ 371 Date: Aug. 30, 2013

(30) Foreign Application Priority Data
Mar. 1, 2011 (FR) 1100614

(51) Int. Cl. C23C 14/35

(52) U.S. Cl. CPC C23C 14/35; B82Y 40/00
USPC 204/192.12; 204/298.16; 204/298.03; 977/890

(57) ABSTRACT

The nanoparticle production device includes a target provided with a nanoparticle source surface, and a magnetron generating a first magnetic field, the target being mounted on the magnetron and the first magnetic field forming field lines at the level of the nanoparticle source surface. The device further includes balancing means of the first magnetic field at the level of the target, arranged to close fleeing field lines of the first magnetic field and to keep said lines closed at the level of said nanoparticle source surface, said balancing means being distinct from the magnetron.

### BACKGROUND OF THE INVENTION

The invention relates to a nanoparticle production device.

The invention also relates to a nanoparticle deposition method.

### STATE OF THE ART

Formation of materials in the form of particles of manometric size applies to numerous applications such as optics, optoelectronics, thermoelectricity or biotechnologies, etc.

In these applications, the synthesized particles often have sizes smaller than 100 nm and preferably comprised between 1 and 20 nm.

To synthesize these nanoparticles, it is possible to use synthesis by liquid means by precipitation of a liquid precursor, synthesis by electrodeposition from a solution, or synthesis in a vacuum by CVD (chemical vapor deposition) or PVD (physical vapor deposition) technique. Vacuum techniques are interesting as they use equipment very close to those usually used in optronics.

However, the CVD or PVD techniques to synthesize nanoparticles do not propose the same degree of control. In the CVD technique, nucleation-growth of the nanoparticles will take place on a substrate, which makes independent control of the size and density of the particles difficult. The PVD technique is therefore preferred.

As illustrated in FIG. 1, a conventional nanoparticle production device comprises a target 1. Target 1 preferably has the shape of a plate and is made from a material from which atoms will be torn off so as to generate the nanoparticles. The surface of the target from which the atoms are torn off is called source surface 1a of the nanoparticles. Target 1 is mounted on a magnetron 2 and source surface 1a of the nanoparticles is opposite magnetron 2. In general manner, a sputtering gas is used for generation of the nanoparticles. The production device can then also comprise a cooled enclosure in which target 1 and magnetron 2 are arranged. Target 1 and magnetron 2 of FIG. 1 then form an element also called cathode sputtering element.

Conventionally, a magnetron 2 comprises, as in FIG. 1, a cathode 3 at the rear of which magnets 4a, 4b are located. A first magnet 4a can have the shape of a hollow cylinder and a second magnet 4b can have the shape of a cylinder that is also hollow, or solid, inserted in the hollow cylinder of first magnet 4a. The polarities of first and second magnets 4a, 4b are reversed. One of the poles of first magnet 4a is directed towards cathode 3, and one of poles of second magnet 4b is directed towards cathode 3, preferably the two poles mentioned being in contact with cathode 3. Target 1 is in direct contact with cathode 3 on one surface of cathode 3 opposite the surface in contact with magnets 4a, 4b.

Opposite the junction between cathode 3 and magnets 4a, 4b, magnetron 2 comprises a contention element 5 made from soft iron. The purpose of this soft iron element 5 is to imprison the field lines of the magnetic field generated by magnets 4a, 4b of magnetron 2 on its rear surface 2a (the front surface being defined by the surface of cathode 3 bearing target 1), and in the particular case of FIG. 1 to make it flow from first magnet 4a to second magnet 4b or vice-versa. To generate the nanoparticles, the magnetic field comprises field lines C which egress from target 1 before re-entering the latter.

In FIG. 1, magnetron 2 further comprises an anode 6 radially surrounding the assembly formed by the magnets/soft iron element 5 and cathode 3.

The document “Modeling metallic nanoparticle synthesis in a magnetron-based nanocluster source by gas condensation of a sputtered vapor” by E Quesnel et al. published on 4 Mar. 2010 on-line by the “Journal of Applied Physics 107, 054309” describes a complete device for vacuum deposition of nanoparticles in which the nanoparticle production device can be used.

The document WO95/12003 describes a device for production of particles from a target. Magnets are arranged in a cathode. A target made from ferromagnetic material is mounted on the cathode. A magnetic shunt is achieved by means of iron elements.

The yield of such a device for vacuum deposition of nanoparticles is not optimum and requires a high-performance cooling system which is therefore costly and fastidious to implement.

### OBJECT OF THE INVENTION

The object of the invention is to provide a nanoparticle production device having an improved sputtered nanoparticle yield.

This object tends to be achieved by means of a device which comprises a target provided with a nanoparticle source surface,
a magnetron generating a first magnetic field, the target being mounted on the magnetron and the first magnetic field forming field lines at the level of the nanoparticle source surface,
balancing means of the first magnetic field, at the level of the target, arranged to close the fleeing field lines of the first magnetic field and keep said lines closed at the level of said nanoparticle source surface, said balancing means being distinct from the magnetron and arranged in such a way that the first magnetic field on the source surface comprises a minimum value Bₘᵢₙ and a maximum value Bₘₐₓ, the dispersion of the first magnetic field defined by the formula

$$\frac{\vert ( \vert {B}_{max} \vert - \vert {B}_{min} \vert ) \vert}{[ \frac{( \vert {B}_{max} \vert + \vert {B}_{min} \vert )}{2} ]}$$

being less than 0.5.

According to a first embodiment, the balancing means comprises a plate provided with a ferromagnetic element, said plate being arranged between the target and the magnetron. The plate can comprise at least one material chosen from Fe, Co, Ni, Mn.

According to a second embodiment, the balancing means comprise a magnetic coil generating a second magnetic field, said magnetic coil being controlled by control means comprising a state in which the fleeing field lines of the first magnetic field are closed, said lines being maintained at the level of said source surface.

According to an alternative embodiment, the absolute value of the difference between Bₘᵢₙ and Bₘₐₓ is less than 5*10⁻² Tesla.

According to one embodiment, the device comprises a temperature measurement sensor arranged facing the source surface.

The invention also relates to use of a nanoparticle production device in a nanoparticle deposition device. The nanoparticle production device can comprise an enclosure in which the magnetron, target and balancing means are arranged, said enclosure comprising a sputtering gas inlet and an outlet opening of the nanoparticles. The deposition device comprises a first chamber into which the outlet opening of the enclosure opens, and a second chamber provided with a substrate for deposition of the nanoparticles, the first chamber communicating with the second chamber via a hole, and said second chamber being at a negative pressure with respect to the first chamber.

The invention also relates to a nanoparticle deposition method using a magnetron on which a target provided with a nanoparticle source surface is mounted, the magnetron generating a magnetic field forming field lines at the level of the nanoparticle source surface, the method comprising an adjustment step of the magnetic field consisting in closing fleeing field lines of the magnetic field and keeping said lines closed at the level of said nanoparticle source surface, adjustment being performed by balancing means distinct from the magnetron so that, after adjustment, the magnetic field on the source surface (1a) of the target comprises a minimum value Bₘᵢₙ and a maximum value Bₘₐₓ, the dispersion of the magnetic field defined by the formula

$$\frac{\vert ( \vert {B}_{max} \vert - \vert {B}_{min} \vert ) \vert}{[ \frac{( \vert {B}_{max} \vert + \vert {B}_{min} \vert )}{2} ]}$$

being less than 0.5.

### BRIEF DESCRIPTION OF THE DRAWINGS

Other advantages and features will become more clearly apparent from the following description of particular embodiments of the invention given for non-restrictive example purposes only and represented in the appended drawings, in which:

FIG. 1 illustrates a nanoparticle production device according to the prior art seen in cross-section.

FIG. 2 illustrates a nanoparticle production device according to a first embodiment seen in cross-section.

FIG. 3 illustrates a cross-sectional view along the line A-A of FIG. 2.

FIG. 4 illustrates a nanoparticle production device according to a second embodiment seen in cross-section.

FIG. 5 illustrates a combination of the first and second embodiments.

FIG. 6 illustrates a particular embodiment of the nanoparticle production device.

FIG. 7 illustrates a plot of the probability of nucleation of nanoparticles seeds versus temperature.

FIG. 8 illustrates a plot representative of the temperature versus the distance from the target.

FIG. 9 illustrates a nanoparticle deposition device.

FIG. 10 illustrates the variation of the temperature versus the distance from the target for a modified device and a standard device.

### DESCRIPTION OF PREFERRED EMBODIMENTS

The device described hereafter differs from those of the prior art in that it comprises balancing means of the magnetic field at the level of the target.

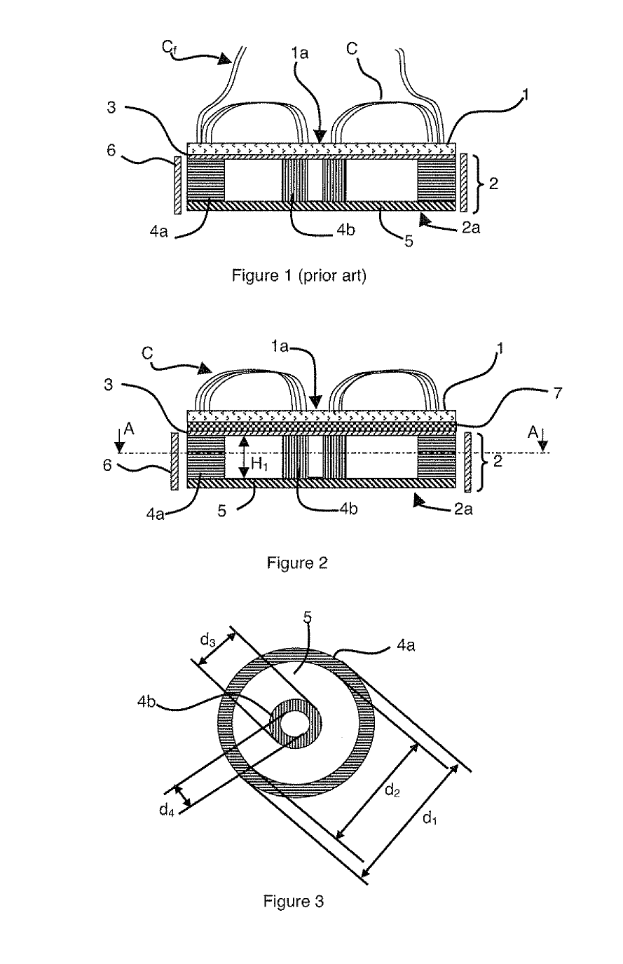

A magnetron according to the prior art is in fact not intrinsically balanced, rather tending to be unbalanced. What is meant by unbalanced is that the magnetic field at the level of the target comprises fleeing field lines C_{f} (see FIG. 1). These fleeing field lines C_{f} are in fact lines which egress from target 1 and move away from target 1 without returning to the latter.

During tests in the scope of the present invention, it was observed that the more unbalanced the magnetron was (i.e. the more the field lines were fleeing) the lower the nanoparticle deposition yield.

It is well known that, by construction, a magnetron is never balanced, although by positioning magnets 4a, 4b of magnetron 2 suitably, it is possible to modify the balance. However by modification of magnets 4a, 4b, a fixed magnetron would be obtained usable with a single type/thickness of target.

By definition, the imbalance of a circular cathode-based magnetron is all the greater the more the absolute value of the magnetic field at the centre of the cathode is different from that of the magnetic field at the periphery of the cathode.

In FIGS. 2 to 5, the nanoparticle production device comprises a target 1 provided with a source surface 1a of the nanoparticles, and a magnetron 2 generating a first magnetic field. The target is mounted on magnetron 2. Naturally, in conventional manner, nanoparticle source surface 1a is opposite the mounting surface of target 1, the mounting surface being directed towards magnetron 2. The first magnetic field forms field lines C at the level of nanoparticle source surface 1a.

Balancing means of the first magnetic field at the level of target 1 are arranged to close fleeing field lines of the first magnetic field and to keep said lines closed at the level of said nanoparticle source surface 1a. These balancing means are distinct from magnetron 2. What is meant in particular by distinct from magnetron is distinct from the magnets generating the first magnetic field.

What is meant by at the level of the source surface of the target is, as illustrated in FIG. 2, that the field lines egress from and re-enter target 1, via nanoparticle source surface 1a, while remaining in proximity to said source surface 1a of target 1. In other words, field lines C are salient from target 1 and remain close to its surface, whereas without the balancing means, certain of these field lines would become fleeing.

As described in the prior art, magnetron 2 can comprise a cathode 3 and a contention element 5 of the field lines, for example made from soft iron, sandwiching magnets 4a, 4b. A first magnet 4a can have the shape of a hollow cylinder and a second magnet 4b can have the shape of a cylinder that is also hollow, or solid according to an alternative embodiment, inserted in the hollow cylinder of first magnet 4a, as illustrated in particular in FIG. 3 representing a cross-section along A-A of FIG. 2. The polarities of the first and second magnets 4a, 4b are reversed. One of the poles of first magnet 4a, for example the south pole, is directed towards cathode 3, and one of the poles of second magnet 4b, for example the north pole, is directed towards cathode 3. The two poles mentioned are preferably in contact with cathode 3. In FIG. 2, the poles opposite those in contact with cathode 3 are preferably in contact with contention element 5. This contention element 5 serves the purpose of imprisoning the field lines of the first magnetic field generated by magnets 4a, 4b of magnetron 2 on the rear surface 2a of magnetron opposite target 1, and to make it flow from first magnet 4a to second magnet 4b or vice-versa.

In other words, magnetron 2 can comprise a cathode 3 provided with the first surface and with a second surface opposite said first face. Magnets 4a, 4b, which may be permanent or not, are mounted on the first surface, and target 1 is mounted on the second face forming the front surface of magnetron 2.

In FIG. 2, magnetron 2 further comprises an anode 6. This anode 6 can for example form a guard surrounding the edges of the cathode 3/magnets 4a, 4b/contention element 5 assembly.

The example of FIG. 2 is relative to a magnetron 2 provided with a circular flat cathode 3 with a diameter of 50 mm.

As illustrated in FIG. 3, first magnet 4a is preferably in the form of a toxoid with a height of 1 cm, an external diameter d₁ of 50 mm and an internal diameter d₂ of 40 mm (hollow cylinder). Second magnet 4b can be a hollow or solid cylinder with an external diameter d₃ of 2 cm, an internal diameter d₄ of 1 cm (if it is hollow), and a height of 1 cm. What is meant by height is the dimension H₁ of FIG. 2, and a dimension not visible in FIG. 3 but oriented perpendicularly to the plane of FIG. 3.

The invention is naturally not limited to the particular example of a magnetron described above. The person skilled in the art will be able to use different magnetrons known to him commonly used in physical vapor depositions. For example, cathode 3 can have the shape of a rectangular plate and magnets 4a, 4b can have the shape of a horseshoe.

In a first particular embodiment that can be seen in FIG. 2, the balancing means comprise a plate 7 comprising a ferromagnetic element. This plate 7 can also be qualified as magnetization plate. Plate 7 is arranged between target 1 and magnetron 2, more particularly between target 1 and cathode 3. Plate 7 can comprise this ferromagnetic element only or an alloy of several ferromagnetic elements. For example, the ferromagnetic element or elements are chosen from Fe, Co, Ni, Mn.

Target 1 can be mounted on cathode 3 of magnetron 2 by interposition of plate 7. In other words, plate 7 can be arranged in direct contact with cathode 3, and plate 7 receives target 1 in direct contact. According to an alternative embodiment, it is possible to stack two targets or two plates 7 made from ferromagnetic material.

In the case of the presence of two targets, it is possible to have a first target in contact for example with cathode 3 and partially covered by the second target so as to produce a mixture of nanoparticles. In other words, the source surface comprises portions of the first target and portions of the second target. The mixture of nanoparticles can also be obtained by means of a target the source surface of which is substantially flat and which is in the form of a mosaic formed by at least two materials. Fixing supports (not shown) not modifying the first magnetic field induced by magnetron 2 can also be used to keep target 1 against cathode 3. In FIG. 2, plate 7 is in contact with a surface of cathode 3 opposite the magnets of magnetron 2.

The thickness of plate 7 is calculated according to the power of magnets 4a, 4b of cathode 3 and to the thickness of target 1 so that the field lines of the first magnetic field are preserved in proximity to source surface 1a of the nanoparticles. In other words, the magnetic permittivity of plate 7 has to be sufficient to guide the magnetic field emanating from cathode 3, but also to enable the field lines of the first magnetic field to egress from the target via source surface 1a of the nanoparticles before re-entering the latter.

The use of such a plate enables an off-the-shelf magnetron to be easily modified at low cost to optimize its yield in the scope of use as nanoparticle production device. Moreover, with a different set of plates 7, it is possible to adapt magnetron 2 with any type of target 1.

For example purposes, plate 7 will have a thickness comprised between 0.05 mm and 10 mm. This thickness will naturally depend on the characteristics of the first magnetic field and on the ferromagnetic characteristics of plate 7.

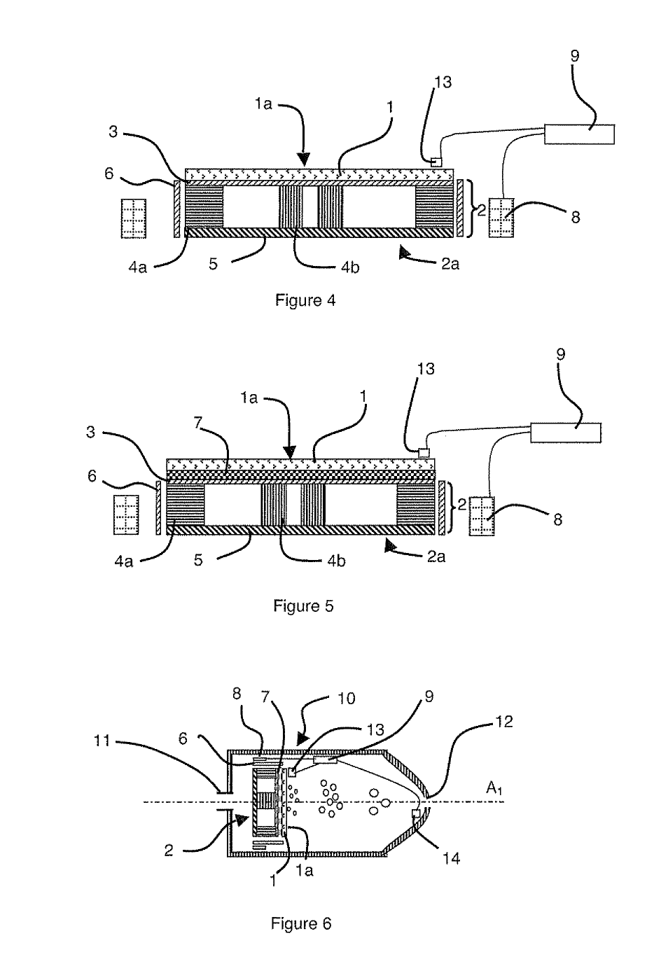

In a second particular embodiment illustrated in FIG. 4, magnetron 2 (identical to that of the first embodiment) is subjected to a magnetic element generating a second magnetic field, external to magnetron 2, enhancing closing of the fleeing field lines of the first magnetic field. This second magnetic field can for example be implemented by a magnetic coil 8 of the balancing means. This coil 8 can be an electromagnet of solenoid type. In addition to coil 8, the balancing means comprise control means 9 controlling coil 8 and comprising a state in which the fleeing field lines of the first magnetic field are closed, and said closed lines are kept at the level of nanoparticle source surface 1a. This state can correspond to a modulation of the second magnetic field to adjust the first magnetic field.

Such a coil 8 can for example be arranged around magnetron 2 in the same plane as the latter. In other words, a magnetron 2 is arranged in the centre of coil 8, which surrounds its edges, the edges of the magnetron corresponding to faces joining its front surface to its rear surface. For example, in the case of a magnetron 2 of circular cross-section, coil 8 can be coaxial to magnetron 2. In FIG. 4, coil 8 surrounds anode 6.

The use of coil 8 is more malleable than the use of the plate having ferro-magnetic properties, although the plate gives better results for a fixed and known configuration. Coil 8 in fact makes it possible on the one hand to adjust the second magnetic field via the direction and the current intensity of coil 8 whatever the first magnetic field, but does on the other hand let certain magnetic field lines parallel to the axis of the magnetron, and therefore participating in a slight unbalance of magnetron 2, escape in a top part of target 1. What is meant by top part is a distance of about 3 cm of target 1 in an opposite direction to magnetron 2 moving away from source surface 1a. What is meant by slight unbalance is that magnetron 2 is better balanced with coil 8 than without.

In the two embodiments, it is possible for certain fleeing field lines to remain, but they are however less numerous.

The two embodiments can also be combined as illustrated in FIG. 5, using the same references as FIGS. 2 and 4, so that their advantages act in synergy to increase the nanoparticle production yield. The advantage of using coil 8 in association with plate 7 is in fact to prevent the detrimental effects mentioned in the second embodiment while at same time keeping a flexibility of adjustment to increase the nanoparticle production yield. Thus, in FIG. 5, the balancing means comprise both plate 7 and coil 8 associated with its control means 9.

Preferably, and in a manner that is valid for the two embodiments and their combination, the balancing means are arranged so that the first magnetic field on source surface 1a of target 1 comprises a minimum value Bₘᵢₙ and a maximum value Bₘₐₓ, the dispersion of the first magnetic field defined by the formula

$$\frac{\vert ( \vert {B}_{max} \vert - \vert {B}_{min} \vert ) \vert}{[ \frac{( \vert {B}_{max} \vert + \vert {B}_{min} \vert )}{2} ]}$$

being less than 0.5 and the absolute value of the difference between Bₘᵢₙ and Bₘₐₓ preferably being less than 5*10⁻² Tesla. The formula is representative of the ratio between |(|Bₘₐₓ|-|Bₘᵢₙ|)| and

$$\frac{( \vert {B}_{max} \vert - \vert {B}_{min} \vert )}{2} .$$

Thus, in the first embodiment for a given magnetron 2, it is possible to choose the right plate 7 by successive tests and measurements, with different plates 7, of the first magnetic field induced at the level of source surface 1a by a gaussmeter so as to achieve the conditions aimed for above.

The second embodiment, for a given magnetron 2, it will be possible to adapt operation of coil 8 according to measurements of the magnetic field induced at the level of source surface 1a by a gaussmeter so as to achieve the conditions aimed for above.

In both cases, for a cathode in the form of a circular plate, Bₘᵢₙ is measured at the centre and Bₘₐₓ along the inner perimeter of the cathode or vice-versa. This can also naturally depend on the positioning of magnets 4a, 4b of magnetron 2.

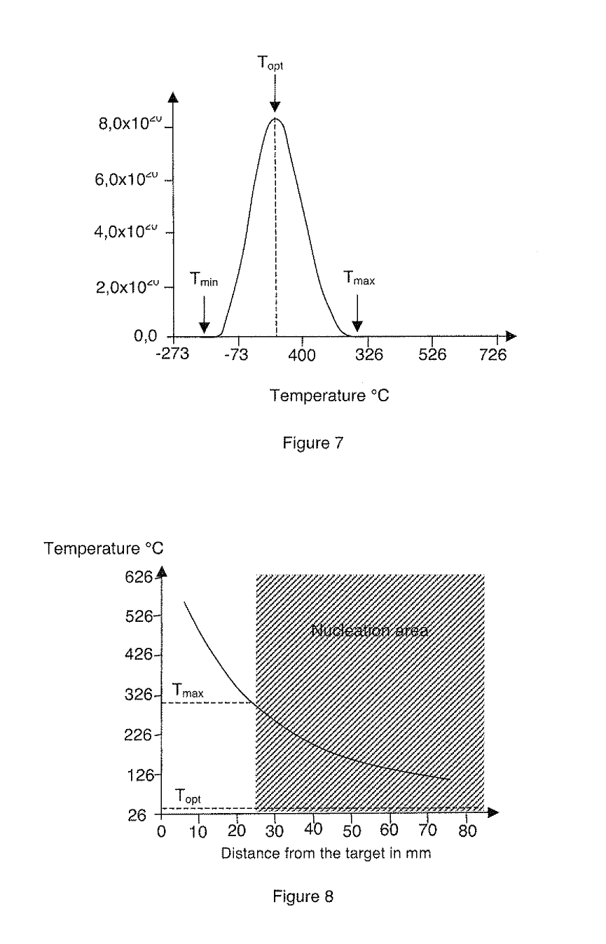

As illustrated in FIG. 6, the nanoparticle production device can further comprise an enclosure 10 in which target 1, magnetron 2 and balancing means 7, 8, 9 are arranged (whether it be in the first embodiment, in the second embodiment or in the combination of the two embodiments). The balancing means, magnetron 2, and target 1 can form an assembly called cathode sputtering element. Enclosure 10 can comprise a gas inlet 11 and an outlet opening 12 for the nanoparticles. Gas inlet 11 and output opening 12 are preferably placed along the same axis A1. Magnetron 2 and its target 1 are preferably situated between gas inlet 11 and outlet opening 12. Source surface 1a of the nanoparticles is directed towards outlet opening 12. This enclosure 10 can be cooled by a cooling element which is not represented.

Thus, in operation, the gas is input to enclosure 10 via gas inlet 11. Anode 6 and cathode 3 of magnetron 2 are polarized so that the target is negatively polarized and the gas in proximity to the target becomes positively ionized.

For example a gas such as Argon will be used, which when reaching the proximity of the target will react in the following manner:

Ar+e⁻→Ar⁺+2e⁻

The electrons generated by this reaction move according to field lines C of the first magnetic field (FIG. 2) and wind around these lines. This winding enables their path to be lengthened, which increases their probability of collision with the Ar gas and therefore the production of Ar⁺ ions. For their part, the generated ions are accelerated by the negative potential of target 1 so as to bombard source surface 1a directed towards outlet opening 12. This bombardment tears atoms from target 1 which are then sent in the direction of outlet opening 12 and then expelled in the form of nanoparticles via outlet opening 12. The greater the distance from target 1 in enclosure 10, the more the torn off atoms agglomerate in the form of nanoparticles of more or less large size, preferably from 1 nm to 10 nm or even 20 nm, and able to reach a size of 100 nm. This agglomeration phenomenon results from the formation of seeds formed by a few atoms torn off the target (nucleation) followed by their growth by accumulation on the seeds of other atoms of the target.

Magnetron 2 associated with balancing means 7, 8, 9 enables the nanoparticle yield to be improved by enhancing nucleation. The quality of nucleation, and therefore of the yield, does in fact depend on the cooling profile when the atoms move away from target 1. In the particular case of target 1 placed in an enclosure 10, the cooling profile corresponds to the variation of the temperature between target 1 and output opening 12.

The nucleation theory shows that nucleation is maximal for a given temperature Tₒₚₜ and can only take place if at one point, in this case of the enclosure, the temperature profile approaches this value. Optimal cooling between target 1 and outlet opening 12 induces nucleation of seeds followed by growth of the latter, which is why costly and complex cooling systems are used in the prior art. As set out in the document “Modeling metallic nanoparticle synthesis in a magnetron-based nanocluster source by gas condensation of a sputtered vapor” published in “Journal of Applied Physics 107, 054309 (2010)” by E. Quesnel et al., there is a large influence between the temperature profile in enclosure 10 and the nanoparticle yield.

FIG. 7 illustrates the number of possible nucleations versus temperature for a copper target material. The curve plot has the form of a Gaussian and makes it possible to determine very clearly that, if the temperature is too hot or too cold, there is no nucleation. In FIG. 7, below −173° C. (Tₘᵢₙ) there is no nucleation and above 326° C. (Tₘₐₓ) there is no nucleation. The optimal temperature Tₒₚₜ represents the peak of the Gaussian, at this temperature nucleation is optimal. The value Tₒₚₜ naturally depends on the target material.

FIG. 8 illustrates the variation of the temperature versus the distance of the location, from target 1, between target 1 and possibly outlet opening 12. At the level of target 1, the temperature is about 580° C., and at the level of opening 12, the temperature is about 76° C. This plot shows the importance of controlling the thermal profile. Indeed, by relating the plot of FIG. 7 with that of FIG. 8, it is possible to determine a first area where any nucleation is impossible and a second area where nucleation is possible. In FIG. 8, the nucleation area extends from 25 mm to output opening 12. Thus, the greater the slope of the curve associated with the temperature decrease when moving away from the target, the larger the nucleation area in enclosure 10 and the greater the yield will be.

The nanoparticle production device described above provided with at least one magnetron 2 and balancing means of the first magnetic field makes it possible to act on the thermal profile. The fleeing field lines do in fact participate in heating of the areas located away from magnetron 2. In the prior art, the enclosure is cooled at very low temperature using for example a coolant liquid such as liquid nitrogen at −196° C. The balancing means enable high nanoparticle synthesis yields to be achieved while at the same time circumventing the need for cooling using coolant liquids at negative temperatures, such as nitrogen for example.

By means of the balancing means, the fleeing field lines are much less numerous, and the thermal profile is therefore better controlled and costly cooling systems can be avoided, a simple water cooling system being able to suffice.

Furthermore, control of field lines C of the first magnetic field also makes it possible to achieve homogenization of the wear of the target with a broadened sputtering ion impact area, thus avoiding premature replacement of the target.

In the second embodiment, and in the variant combining the first and second embodiments, it is then also possible to calibrate the device in precise manner without requiring measurements of the first magnetic field at the level of the target. The nanoparticle production device can therefore comprise, as illustrated in FIGS. 4 to 6, a first temperature measurement sensor 13 arranged facing source surface 1a and arranged to give a temperature representative of the temperature preferably at the level of nanoparticle source surface 1a. First sensor 13 is if necessary arranged in enclosure 10 between surface 1a and output 12. This first sensor 13 can be located a few centimetres from source surface 1a, for example between 1 cm and 5 cm. In a calibration phase, magnetron 2 can be polarized and the temperature be measured by first sensor 13, once the latter is stabilized. This measured value can then be transmitted to control means 9 of coil 8 designed to make the second magnetic field of coil 8 vary so as to obtain the smallest possible temperature value measured by first sensor 13. Considering that the thermal profile decreases the farther one moves away from target 1, the temperature at a given point is at its minimum when magnetron 2 is the most balanced. In this configuration the probabilities of reaching or approaching Tₒₚₜ are increased.

A particular embodiment of the calibration phase can be implemented by a loop of steps. First of all the current of coil 8 is zero, then a first temperature measurement T₀ is made. The value of the current in coil 8 is then incremented, and a second temperature measurement T₁ is made, and if T₁-T₀<0, the coil current continues to be incremented until Tₙ₊₁-Tₙ is positive. If Tₙ₊₁-Tₙ is positive, then the magnetron is considered as being balanced.

According to an alternative embodiment, the device can further comprise a second temperature measurement sensor 14, preferably arranged near to outlet opening 12 (see FIG. 6) and for example connected to control element 9. Control element 9 can then modulate the second magnetic field of coil 8 according to the temperature difference between first sensor 13 and second sensor 14. The use of two sensors enables a mean temperature decrease slope to be determined, the more the slope is inclined in the direction of the vertical, the better the yield will be.

The measurements using one or two temperature sensors can also be used in the first embodiment in order to choose the right plate from a set of ferro-magnetic plates. Temperature measurements are thus made for each plate, and the plate associated with the smallest measurement, or with the most rapid slope decrease, is then chosen.

The nanoparticle production device as described above can be used in a nanoparticle deposition device, preferably in a vacuum.

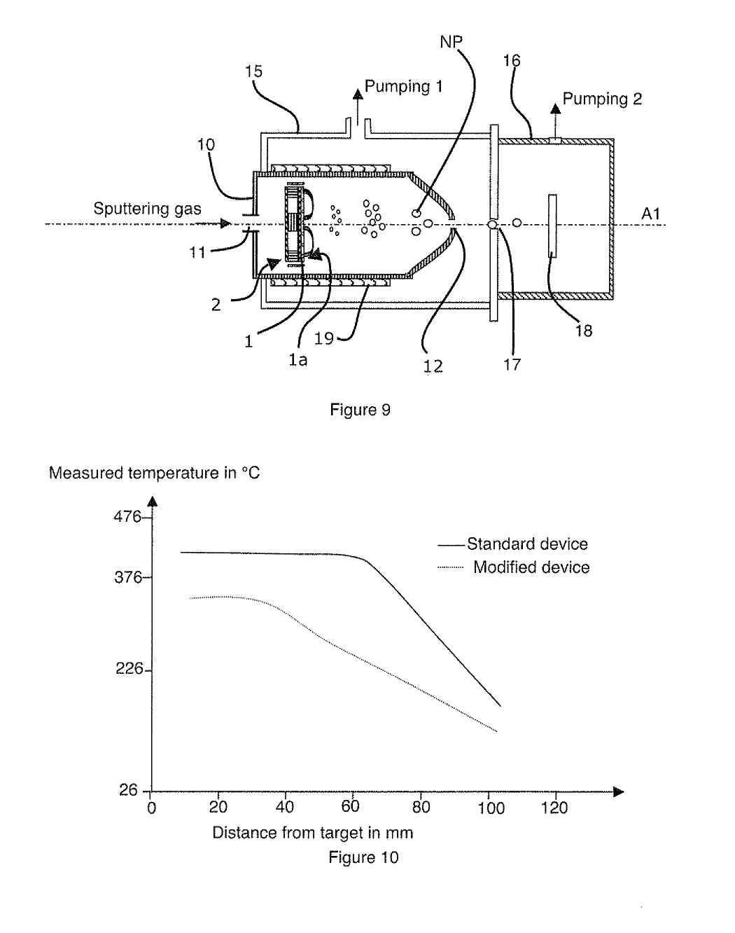

FIG. 9 illustrates a particular embodiment of a deposition device of nanoparticles NP. Such a deposition device comprises a first chamber 15 and an enclosure 10 in which magnetron 2, target 1 and the balancing means (not visible in FIG. 9) are arranged. Enclosure 10 comprises a sputtering gas inlet 11 and a nanoparticle outlet opening 12. The outlet opening 12 of nanoparticles NP opens into first chamber 15. The device further comprises a second chamber 16 provided with a substrate 18 for deposition of the nanoparticles, called deposition chamber, first chamber 15 communicating with second chamber 16 via a hole 17. Second chamber 16 is at negative pressure with respect to first chamber 15. It is this pressure difference that enables nanoparticles NP to be projected from enclosure 10 into first chamber 15, and then into second chamber 16 to be deposited on substrate 18. By reaction with the gas, magnetron 2 and associated target 1 enable a vapor of the material or materials of the target to be generated. The nanoparticles are thus generated from source surface 1a of the target along axis A1 until they reach outlet opening 12, and are then propelled into the deposition chamber via hole 17 in the direction of associated deposition substrate 18.

In order to achieve the overpressure, the deposition device can comprise a first pumping element (pumping 1) designed to create a vacuum in first chamber 15, and a second pumping element (pumping 2) designed to create a vacuum in second chamber 16.

The inside of enclosure 10 is preferably cooled by a cooling element 19, for example water (typically comprised between 10° C. and 25° C.) to partially regulate the thermal profile of the gas in enclosure 10 in combination with the effects of the balancing means. This can for example be implemented by making the coolant flow around enclosure 10. In other words, adjusting the balance of a magnetron enables the nanoparticle deposition yield to be increased by controlling the spatial profile of the vapor it emits, while at the same time reducing the resources necessary for cooling of enclosure 10.

Gas inlet 11, outlet opening 12 of enclosure 10, and hole 17 enabling communication between first chamber 15 and second chamber 16 are preferably situated along the same axis A1. This enhances movement of nanoparticles NP in the sputtering gas diffusion direction. Magnetron 2 can be arranged along this axis A1, source surface 1a then being directed towards opening 12.

Naturally, this particular example embodiment of the nanoparticle deposition device is not limitative, and the person skilled in the art will be able to adapt other deposition device structures on the basis of the nanoparticle production device as described in the foregoing.

In operating tests, two identical deposition devices using a silver target were used, the only difference being that one of the devices was modified to comprise the balancing means of the first magnetic field as described in the foregoing. The standard device according to the prior art was biased so as to produce a sputtering current of 200 mA, the mean size of the silver particles was measured at 5 nm, and the deposited mass per hour was from 100 to 150 ng/cm². The sputtering current generates an ion flux which bombards the target, the greater the flux, the denser the atom vapor of the target and the more nanoparticles are formed. The modified device was biased with a sputtering current of 150 mA, the mean size of the silver particles was measured at 5 nm, and the deposited mass per hour was from 200 to 250 ng/cm². Thus, even with a lower sputtering current, the deposited mass was higher due to the balancing means used to improve the yield. The gain on the number of deposited particles is of a factor two, whereas the sputtering current is 25% lower. The decrease of the sputtering current is directly related to a 25% decrease of the material of the target consumed to obtain this result.

In another particular implementation example, the target used is a germanium target. Deposition experiments were carried out with a standard nanoparticle production device chosen such that the dispersion of its magnetic field was greater than 0.5 and the absolute value of the difference between Bₘᵢₙ and Bₘₐₓ was about 90 mT i.e. 9*10⁻² Tesla. A device with identical characteristics was modified with balancing means in such a way that the dispersion was adjusted to 0.35 and the absolute value of the difference between Bₘᵢₙ and Bₘₐₓ to about 30 mT i.e. 3*10⁻² Tesla.

These two devices enabled the thermal profiles of FIG. 10 to be obtained under similar operating conditions (identical gas flowrate and gas, same coolant flowrate to cool the enclosure). The only difference lies in the use of a weaker sputtering current 200 mA for the device without the balancing means and 300 mA for the modified device. It can be observed in FIG. 10 that the modified device (equipped with the balancing means) generates a much better cooled vapor despite a more intense vapor due to a higher sputtering current 30%.

This improvement of the thermal profile for synthesis of germanium nanoparticles enables a large gain to be obtained, which is the objective sought for. Furthermore, in this test, the mass flux of particles of the standard device was measured as being less than 1 ng/cm² per minute, whereas with the modified device it is greatly in excess of 100 ng/cm² per minute.

The industrial applications of the present deposition device are relative to any product using nanoparticles for essentially surface devices the size of which ranges from a few square millimetres to a few square centimetres. For example purposes, optoelectronic detectors, simple sensors, imagers, solar cells, data storage based on optics and/or magnetism, fuel cells, micro-batteries, any electromechanical device using catalyser nanoparticles, or thermoelectric devices etc. can be cited.

The nanoparticle production device presents the advantage of being close to the magnetron structures commonly used in PVD depositions.

The invention also relates to a nanoparticle deposition method using a magnetron 2 on which a target provided with the nanoparticle source surface 1a is mounted. Magnetron 2 generates a magnetic field forming field lines at the level of nanoparticle source surface 1a. The method comprises an adjustment step of the magnetic field consisting in closing the fleeing field lines of the magnetic field and keeping said lines closed at the level of said nanoparticle source surface 1a. Adjustment is performed by balancing means distinct from the magnetron. In the method described above, all the characteristics applicable to the magnetron (and to the nanoparticle production device) described are applicable, in particular after adjustment the magnetic field on source surface 1a of the target can comprise a minimum value Bₘᵢₙ and a maximum value Bₘₐₓ, the dispersion of the magnetic field defined by the formula

$$\frac{\vert ( \vert {B}_{max} \vert - \vert {B}_{min} \vert ) \vert}{[ \frac{( \vert {B}_{max} \vert + \vert {B}_{min} \vert )}{2} ]}$$

being less than 0.5.

Typically, the adjustment step is performed before deposition of nanoparticles on a support substrate is performed, i.e. preferably before sputtering of the gas designed to react with the target. Examples of adjustment from a gaussmeter or a temperature sensor are described in the foregoing. After adjustment, it is possible to bias the magnetron and to then spray the sputtering gas so that the latter reacts with the target to generate nanoparticles which will be deposited on a substrate.

The electric power supply of the magnetron can be continuous, pulsed, in sine wave mode, low frequency or radiofrequency.

The magnets of the magnetron can be permanent or not.

The target can comprise metallic, semiconducting or dielectric materials. Preferably, the target does not comprise any ferromagnetic materials. Should the target comprise ferromagnetic elements, the balancing means are naturally distinct from the target and will advantageously enable the first magnetic field to be balanced. Preferably, if the target comprises ferromagnetic elements, the embodiment or variant with the coil will be used which will be able to adjust first magnetic field as the material of the target is progressively consumed.

Preferably, the target will have a base formed by at least one material chosen from Si, Ge, Co, Ni, Ag, Cu, Pt, etc.

1-10. (canceled)

11. A nanoparticle production device comprising:
a target provided with a nanoparticle source surface,
a magnetron configured for generating a first magnetic field forming field lines at the level of the nanoparticle source surface, the target being mounted on the magnetron,
a balancing device distinct from the magnetron and configured for balancing the first magnetic field at the level of the target, the balancing device being arranged to close fleeing field lines of the first magnetic field and to keep said lines closed at the level of said nanoparticle source surface, the balancing device being arranged such that the first magnetic field on the nanoparticle source surface comprises a minimum value Bₘᵢₙ and a maximum value Bₘₐₓ, the dispersion of the first magnetic field defined by the formula
$$\frac{\vert ( \vert {B}_{max} \vert - \vert {B}_{min} \vert ) \vert}{[ \frac{( \vert {B}_{max} \vert + \vert {B}_{min} \vert )}{2} ]}$$
being less than 0.5.

12. The device according to claim 11, wherein the balancing device comprises a plate provided with a ferromagnetic element, said plate being arranged between the target and the magnetron.

13. The device according to claim 12, wherein the plate comprises at least one material chosen from Fe, Co, Ni, Mn.

14. The device according to claim 11, wherein the balancing device comprises:
a magnetic coil configured for generating a second magnetic field,
a control system configured for controlling the magnetic coil so as to define a first state wherein fleeing field lines of the first magnetic field are closed, said closed lines being kept at the level of said nanoparticle source surface.

15. The device according to claim 11, wherein an absolute value of a difference between Bₘᵢₙ and Bₘₐₓ is less than 5*10⁻² Tesla.

16. The device according to claim 14, comprising a temperature measurement sensor arranged facing the source surface.

17. Nanoparticle deposition device comprising a nanoparticle production device according to claim 11.

18. Nanoparticle deposition device according to claim 17 comprising:
an enclosure in which the magnetron, the target and the balancing device are arranged, said enclosure comprising a sputtering gas inlet and an outlet opening of the nanoparticles,
a first chamber into which the outlet opening of the enclosure opens,
a second chamber provided with a nanoparticle deposition substrate, the first chamber communicating with the second chamber via a hole, and said second chamber being at negative pressure with respect to the first chamber.

19. Nanoparticle deposition device according to claim 18 comprising a cooling element configured for cooling the inside of the enclosure.

20. A nanoparticle deposition method comprising:
providing a target having nanoparticle source surface mounted on a magnetron, and a balancing device distinct from the magnetron
generating a magnetic field forming field lines at the level of the nanoparticle source surface by means of the magnetron,
performing an adjustment step of the magnetic field with the balancing device, the adjustment step including:
closing fleeing field lines of the magnetic field and
keeping said lines closed at the level of said nanoparticle source surface,
causing a dispersion of the magnetic field defined by the formula
$$\frac{\vert ( \vert {B}_{max} \vert - \vert {B}_{min} \vert ) \vert}{[ \frac{( \vert {B}_{max} \vert + \vert {B}_{min} \vert )}{2} ]}$$
being less than 0.5, the magnetic field on the source surface of the target comprising a minimum value Bₘᵢₙ and a maximum value Bₘₐₓ.
